(19) United States
(12) Patent Application Publication
(10) Pub. No.: US 2010/0141539 A1
(43) Pub. Date: Jun. 10, 2010

(54) Antenna system

(76) Inventors: Michael Thole, Hildesheim (DE); Bert Jannsen, Lehre (DE); Thomas Malzahn, Rheine (DE)

Correspondence Address: KENYON & KENYON LLP, ONE BROADWAY, NEW YORK, NY, 10004, US

(21) Appl. No.: 11/988,909

(22) PCT Filed: May 30, 2006
(86) PCT No.: PCT/EP2006/062713

§ 371 Date: Feb. 23, 2010

(30) Foreign Application Priority Data
Jul. 15, 2005 (DE) 102005033088.6

(51) Int. Cl. H01Q 1/32; G01R 29/08

(52) U.S. Cl. 343/703; 343/713; 343/720

(57) ABSTRACT

In an antenna array, in particular for diversity operation, a cohesive radiofrequency-conductive area (1) is provided, to which switchable impedances (7) are coupled in highly resistive fashion. In order to output the antenna signals, at least one tap point (6b) is provided in particular at a highly resistive point at the outer edge of the conductive area (1).

### FIELD OF THE INVENTION

The present invention is directed to an antenna system for diversity operation in a motor vehicle in particular, having at least one cohesive high-frequency-conductive surface, which is insulated with respect to a surrounding grounding surface, e.g., the vehicle body.

### BACKGROUND INFORMATION

European Published Patent Application No. 1 076 375 describes such an antenna system in which boundary conductors of a predetermined minimum length are designed as low-resistance coupling conductors which are provided between a switchable terminating impedance and a low-resistance antenna signal tap point.

### SUMMARY

With the measures as described herein, i.e., at least one switchable terminating impedance which is coupled to the at least one conductive surface with a high resistance and at least one tap point for antenna signals on the conductive surface, in particular at a high-resistance point in its outer border, it is possible to achieve improved EMC properties and an improved high-frequency performance. European Published Patent Application No. 1 076 375 also describes the need for wide conducting structures due to the low-resistance coupling conductors. One disadvantage of these wide conducting structures is the space required and the resulting proximity to the vehicle body and other conductors, e.g., the lead for the heating power, so that strong coupling is established. This reduces EMC properties with respect to interfering influences and also in particular reduces AM performance. The high-resistance coupling according to example embodiments of the present invention having at least one switchable terminating impedance and the preferred connection of the tap point for antenna signals on the conductive surface at a high-resistance point in its outer border allow the use of high-resistance lines without any special measures for adjusting the characteristic wave impedance and the resulting signal interference and losses. High-resistance lines may be implemented with narrow conduction widths, which greatly reduces the space required. The high-resistance coupling and design of the supply lines and the resulting reduction in space required allow more degrees of freedom in the design of the black print associated with this in or on the vehicle window. In contrast with European Published Patent Application No. 1 076 376, where certain minimum lengths are obligatory for the low-resistance coupling conductors, such lengths are not necessary with the conductor structures of the antenna system according to example embodiments of the present invention to achieve a clear definition of the diversity effect. In this way the antenna system may be used to advantage for smaller vehicle windows. In addition, the high-resistance supply lines between the tap point for antenna signals and the analyzer unit, e.g., antenna amplifiers of a receiving unit, as well as between the high-frequency-conductive surface and the at least one terminating impedance, may also be used with to influence the directional characteristic and thus for the reception level of the antenna, which allows a targeted design of the diversity function of the antenna system.

The conductor structure of the heating conductor field of the rear window in particular may be used as an high-frequency-conductive surface or it may be implemented as a transparent conductive coating in or on the vehicle window into which the high-resistance supply lines may be integrated. For high-resistance coupling of the tap point to the high-frequency-conductive surface, a heating conductor may be used on the outer edge of the heating field, which has a higher resistance anyway than a collective conductor connecting the heating conductors. The adjustment of the switchable terminating impedance(s) may be improved via additional conductors, in particular perpendicular to the heating conductors, normally situated in parallel, and thus the diversity effect may be potentiated. Multiple switchable terminating impedances may also be provided as well as additional tap points for antenna signals. The different antenna signals may be fed to a common analysis by a diversity analyzer unit.

The heating field may also be coupled to another antenna structure, optionally for another frequency range, e.g., TV, DAB, in which the coupling may be implemented by discrete components and/or by line coupling. The two antenna surfaces are combined by this coupling to form a joint high-frequency-conductive surface which has an improved antenna gain, in particular in the low-frequency AM range, e.g., the LMS range.

For the particular impedance adjustment of the impedance at the antenna signal tap point to the impedance of an analyzer circuit, e.g., the antenna amplifier of a receiving unit, an adjustment network may be provided, in particular in different switching states of the terminating impedance(s).

Antenna signal strength, as a function of which the switching states of the terminating impedance(s) are varied, may be detected via an analyzer unit.

Exemplary embodiments of the present invention are illustrated in greater detail on the basis of the drawings.

### BRIEF DESCRIPTION OF THE DRAWINGS

FIG. 1 shows the basic principle of an antenna system according to example embodiments of the present invention,

FIG. 2 shows an antenna system having a plurality of switchable terminating impedances,

FIG. 3 shows an antenna system having a plurality of switchable terminating impedances and a plurality of antenna signal tap points,

FIG. 4 shows an antenna system according to an example embodiment of the present invention having additional antenna conductors perpendicular to the conductors of the heating field,

FIG. 5 shows an antenna system according to FIG. 4 having additional antenna conductors as well as example embodiments for their intersections with the conductors of the heating field,

FIG. 6 shows an antenna system according to FIG. 5 having additional antenna conductors of various lengths,

FIG. 7 shows the example embodiment for coupling the terminating impedances to analyzer units,

FIGS. 8 through 11 show different example embodiments of the terminating impedances,

FIG. 12 shows the separation of the heating circuit and antenna signal circuit,

FIG. 13 shows a plurality of heating fields being interconnected to form an antenna system,

FIG. 14 shows a plurality of heating fields being interconnected to form an antenna system over switchable terminating impedances,

FIG. 15 shows the control of the controllable terminating impedances,

FIG. 16 shows an antenna signal analysis with an adjustment circuit.

### DETAILED DESCRIPTION

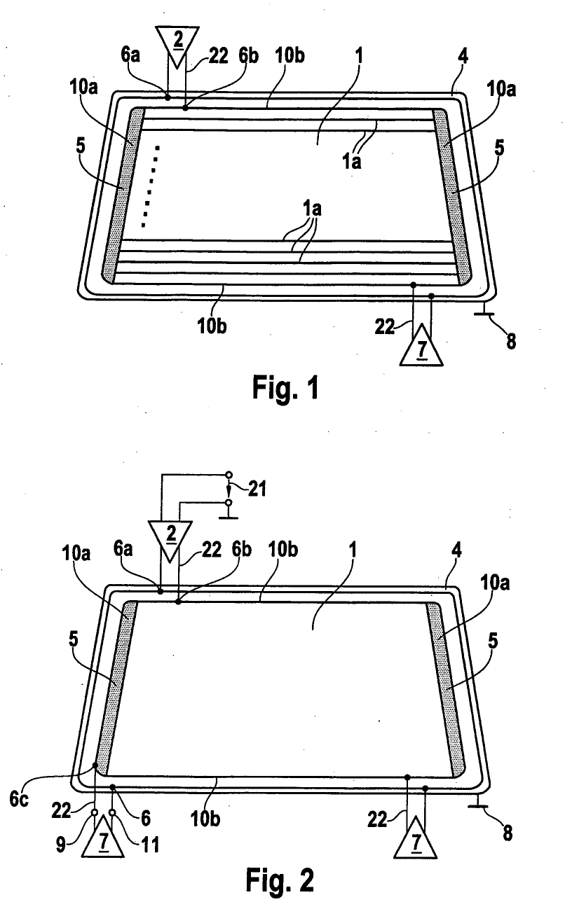

FIG. 1 shows an antenna system according to an example embodiment of the present invention for diversity operation in the VHF range in a motor vehicle in particular. The antenna system has a cohesive high-frequency-conductive surface 1, which has horizontal and/or perpendicular conductors of a heating field in or on a vehicle window, in particular the rear window or a conductive coating, e.g., a vaporized metal transparent vehicle window or sandwich structure. The edges, i.e., the outer border of high-frequency-conductive surface 1, are insulated from a grounding surface surrounding them, e.g., vehicle body 4. In the exemplary embodiment shown in FIG. 4, high-frequency-conductive surface 1 is designed as a rectangle. It may also be trapezoidal or structured in some other way in or on the vehicle window.

High-resistance supply lines 22 (the term “high resistance” as used hereinafter indicates a value of more than 10 ohm, e.g., 50 ohm or 75 ohm in the case of characteristic wave impedance Z0 of a coaxial cable) are used for coupling high-frequency-conductive surface 1 and/or its tap points 6b for antenna signals to a following analyzer unit, e.g., antenna amplifier 2 of receiving units. Such high-resistance supply lines 22 are provided between high-frequency-conductive surface 1 and terminating impedances 7. The latter are designed to be switchable. Reference point—ground 8—of tap points 6b is vehicle body 4 and/or a separate return path to the negative pole of the automotive battery. Due to high-resistance coupling 22 (high characteristic wave impedance Z0) of switchable terminating impedances 7, the directional characteristics and thus the reception level of the antenna are influenced, so that a diversity function of the antenna is achieved. Tap points 6b expediently have a ground terminal 6a on body 4 in their proximity or a separate peripheral ground line, e.g., in the black print area.

In the exemplary embodiment according to FIG. 1, low-resistance boundary conductors 10a in the form of busbars 5 are provided, connecting the conductors 1a that run parallel to one another in heating field 1 at their ends. The heating power is fed into these busbars 5, causing heating to thaw and device the vehicle window in high-resistance conductors (>10 ohm) 1a. Tap point 6b for the antenna signals is preferably located at a high-resistance point in the outer edge of high-frequency-conductive surface 1. Terminating impedances 7 are coupled to an high-frequency-conductive surface 1 with a high resistance. Either through their high-resistance supply lines 22 and/or through coupling to a high-resistance point on conductive surface 1. As FIG. 1 shows, high-resistance coupling of tap points 6b as well as terminating impedance 7 is accomplished at a high-resistance boundary conductor 10b, in contrast with European Published Patent Application No. 1 076 375. For sharper definition of the diversity effects, tap points 6b and coupling of terminating impedance 7 should be situated at a definite distance from one another. This is implemented in FIG. 1 by the fact that the coupling of terminating impedance 7 takes place at an opposite boundary conductor 10b of the conductive surface. However, the requirement for a minimum distance of λ/10 (λ=wavelength of the antenna signals) is not necessary, nor is a low-resistance coupling conductor such as that described in European Published Patent Application No. 1 076 375. Boundary conductors 10a and 10b of high-frequency-conductive surface 1 may be part of a heating field or the border of a conductive surface.

FIG. 2 shows two switchable terminating impedances 7, one impedance leading via its high-resistance supply line 22 to connecting point 6c at a low-resistance boundary conductor 10a and the other leading via its supply line 22, also at a high resistance, to high-resistance boundary conductor 10b.

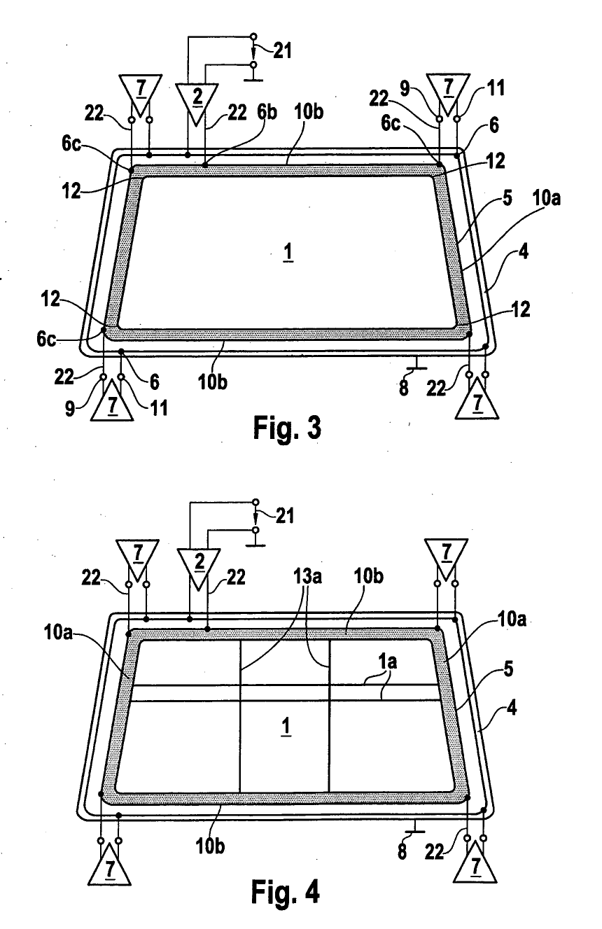

FIG. 3 shows four switchable terminating impedances 7 situated at four corners 12 of conductive surface 1. The antenna signals are picked up at only one tap point 6b.

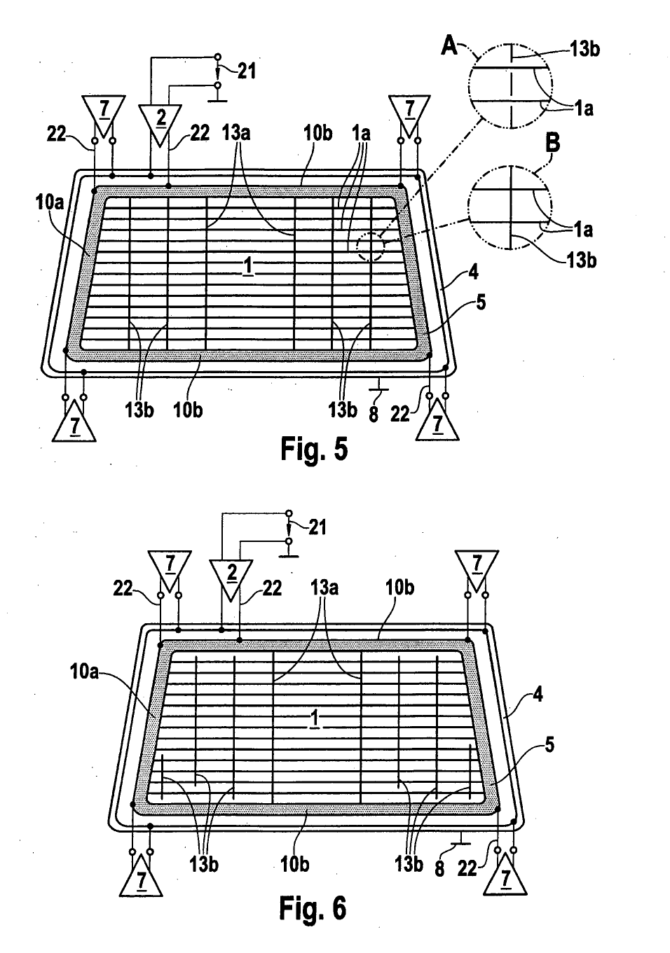

In addition to conductors 1a of the heating field, additional antenna conductors 13a (FIG. 4) and, if necessary, other antenna conductors 13b (FIG. 5) may also be provided, running perpendicular to conductors 1a of the heating field. Additional antenna conductors 13a are usually provided to amplify the antenna effect. Other additional antenna conductors 13b according to example embodiments of the present invention, which are situated closer than additional antenna conductors 13a to the terminating impedances, are preferably used for adjusting terminating impedances 7 and contribute toward improving their switching effect and thus toward increasing the diversity function. Either conductors 1a of the heating field running horizontally and parallel to one another are connected completely conductively to additional antenna conductors 13b, which run perpendicularly (subview B of FIG. 5), or additional antenna conductors 13a, which run perpendicularly, are eliminated in the area where they intersect with horizontal conductors 1a of the heating field (subview A of FIG. 5). High-frequency-capacitive coupling comes about due to the electrical interruption. The number (even and uneven) and the position (inside and/or outside additional antenna conductors 13a) of other additional antenna conductors 13b may be selected freely. However, a symmetrical configuration is preferably advisable. One alternative to the example embodiment according to FIG. 5, in which other additional perpendicular antenna conductors 13b always run continuously from the upper edge to the lower edge of the heating field, is shown in FIG. 6, where other additional perpendicular antenna conductors 13b are provided over only a partial length of the heating field width and thus also come in high-frequency contact with only a portion of horizontal conductors 1a of the heating field.

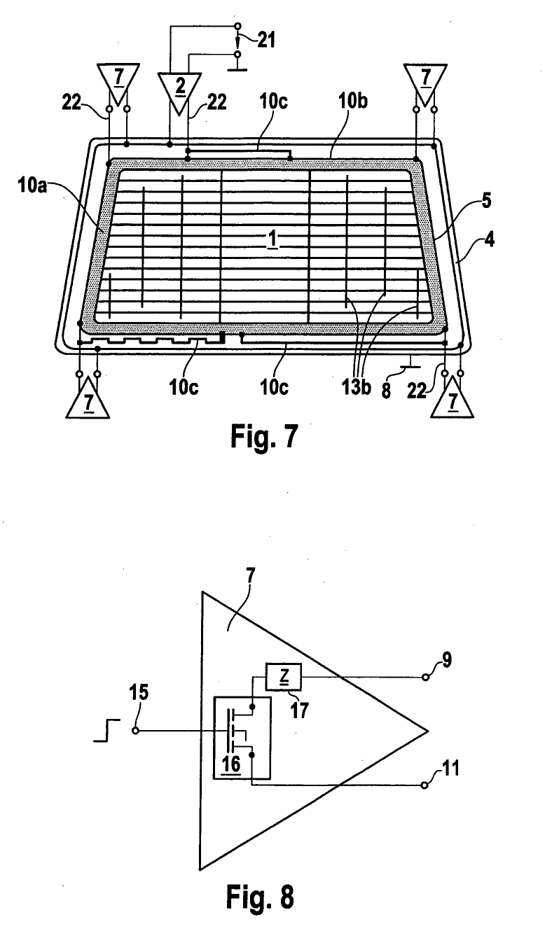

The coupling of terminating impedances 7 to boundary conductors 10a or 10b may take place via direct short connections 22 as in the previous exemplary embodiments, i.e., the connection points of terminating impedances 7 via the high-resistance supply lines to the conductive surface are in the vicinity of terminating impedances 7, or via longer lines 10c which are designed both as cables or through a wide variety of line structures in or on the window (FIG. 7). Longer lines 10c are preferably routed in parallel to boundary conductors 10b, so that an additional capacitive coupling is possible. Longer lines 10c may also be designed as spur lines, i.e., the connection to conductive surface 1 occurs in the vicinity of terminating impedance(s) 7 as well as at the open end of these lines 10c. Lines 10c, like the conductive transparent coating or the conductors of the heating field and high-resistance supply lines 22 used for coupling, may be applied to the glass surface or incorporated into the laminated safety glass. Lines 10c and supply lines 22 may be applied as conductive coatings in or on the glass surface, but they normally have a greater conductivity than conductive surface 1. Their resistance and/or characteristic wave impedance Z0 may be adjusted through the width of the conductors. With surfaces that are poor conductors, in particular when transparent, high-resistance lines 10c and 22 having a high characteristic wave impedance may be formed by structures from the poor conducting surface or by additional conductors of another material, in particular in the invisible edge area of the glass surface.

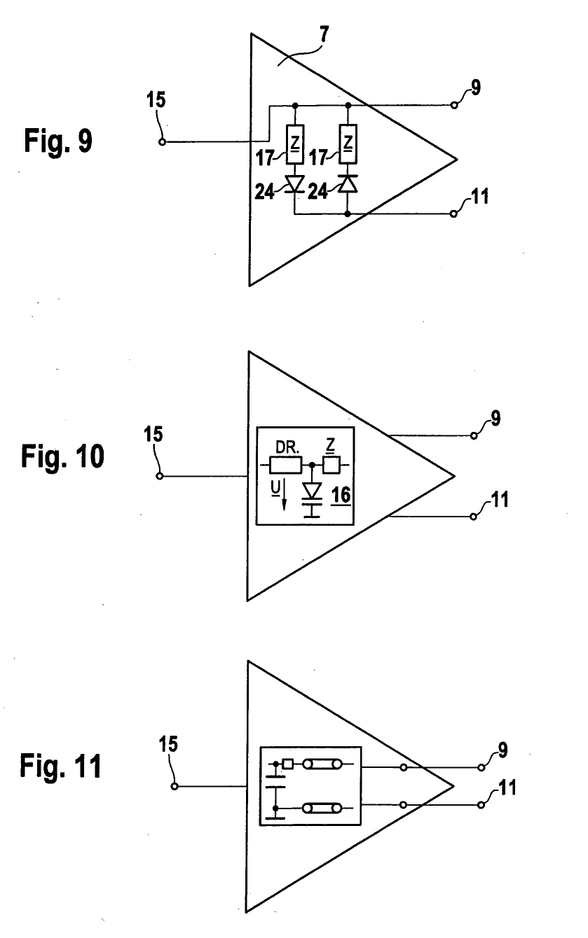

Terminating impedances 7 may be designed in a variety of ways. FIG. 8 shows a terminating impedance 17, which supplies a corresponding terminating impedance for termination on supply line 22 via a field effect transistor 16 and a corresponding activation signal 15 between terminals 9 and 11. FIG. 9 shows an example embodiment having diode impedance networks. Depending on control signal 15, one of diodes 24 becomes conducting or blocked and thus one of impedances 17 is switched between output terminals 9 and 11. FIG. 10 shows a capacitance diode 16, which connects the capacitance that depends on control voltage 15 in series to an impedance Z. FIG. 11 shows the example embodiment of impedance Z from FIG. 10 as a line segment ending in terminals 9 and 11. A simulation of an impedance by a line transformation is feasible with this example embodiment. Not all terminating impedances 7 shown in the exemplary embodiments need be designed to be controllable. One or more of terminating impedances 7 may also be connected to a fixed value. In addition to impedances that are switchable in a loss-free manner, impedances that are subject to loss may also be provided.

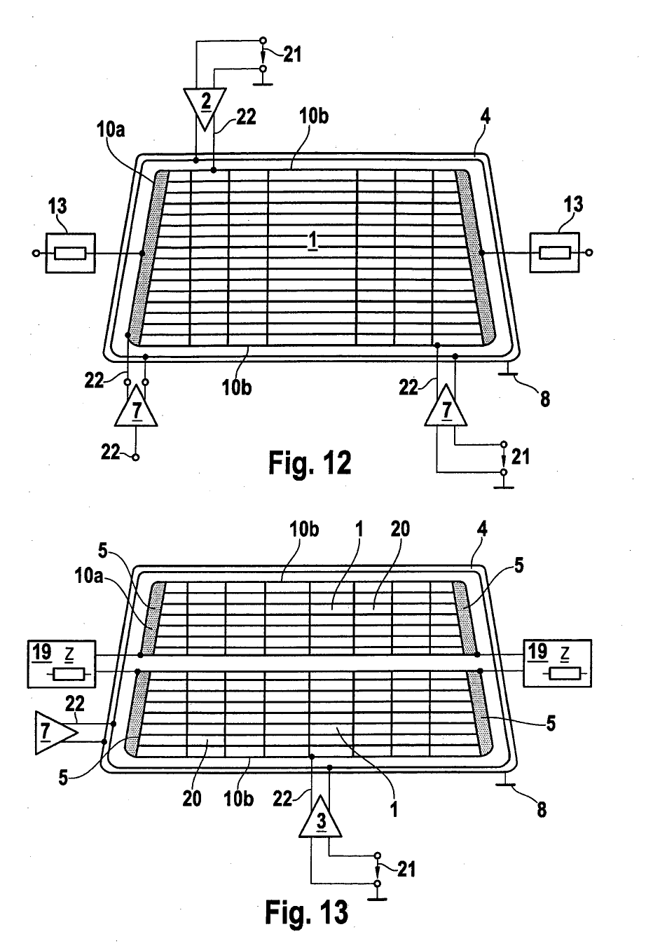

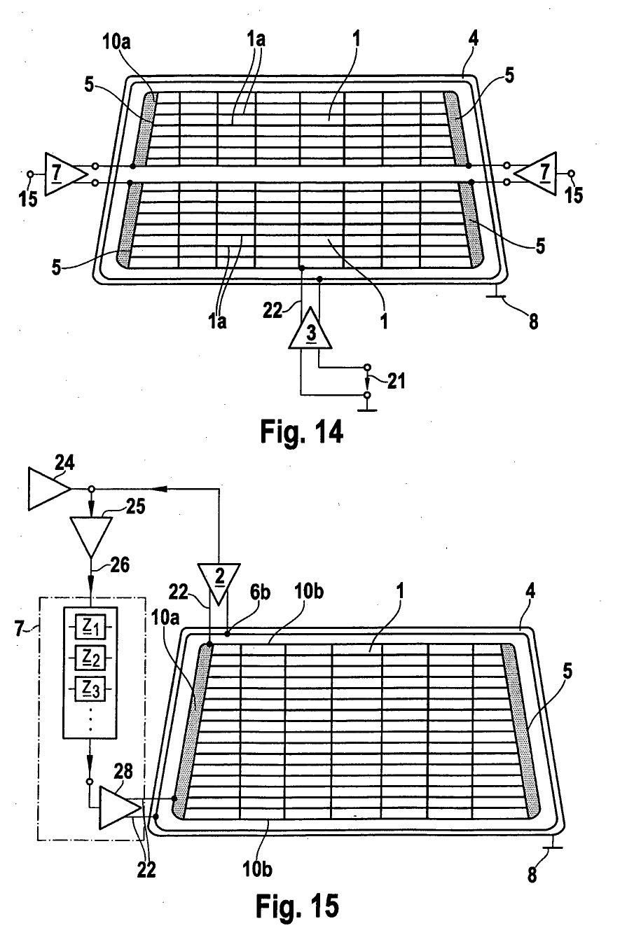

Low-pass filters 13, e.g., in the form of throttles, are connected to the heating current leads to separate the heating circuit from the antenna signal circuit (FIG. 12).

In the case of a plurality of separate heating fields according to FIG. 13, they are combined by couplings in the form of discrete high-frequency-conductive components 19 and/or by line couplings to form a common high-frequency-conductive surface. For line couplings, the conductors of the heating field or the additional and/or other line structures and, if necessary, line structures between heating fields that are separate from one another may be used. Additional antenna structures for another frequency range, e.g., the TV range, may also be coupled in such a way as to improve the high-frequency-conductive surface for lower frequency ranges, e.g., LMS, and improve the antenna gain.

Instead of discrete components 19, switchable terminating impedances 7 may also be used according to 14 for coupling a plurality of heating fields and/or heating field(s) to additional antenna structures.

FIG. 15 shows the control of switchable terminating impedances 7 as a function of the antenna signal strength. For this, the antenna signal picked up at tap point 6b and sent, after amplification by antenna amplifier 2, to receiving unit 24 is analyzed for its signal strength in an antenna diversity analyzer unit 25. On occurrence of reception interference, e.g., a field strength collapse, antenna diversity analyzer unit 25 supplies a switching signal 26 to an impedance network 27, which then relays an impedance other than that switched previously, e.g., Z2 instead of Z1, to amplifier 28, which is coupled via high-resistance supply line 22 to conductive surface 1 with a high resistance. Impedance network 27 together with amplifier 28 forms switchable terminating impedance 7. With the switching of another impedance Z . . . , terminating impedance 7 changes, so that a different antenna signal appears at tap point 6b in the sense of antenna diversity. If its strength is high enough, the newly connected impedance value is retained. Otherwise, diversity analyzer unit continues the switching operation until the antenna signal obtained is strong enough. The selected switching states thus act in the sense of antenna diversity to counteract a decline in antenna signal strength.

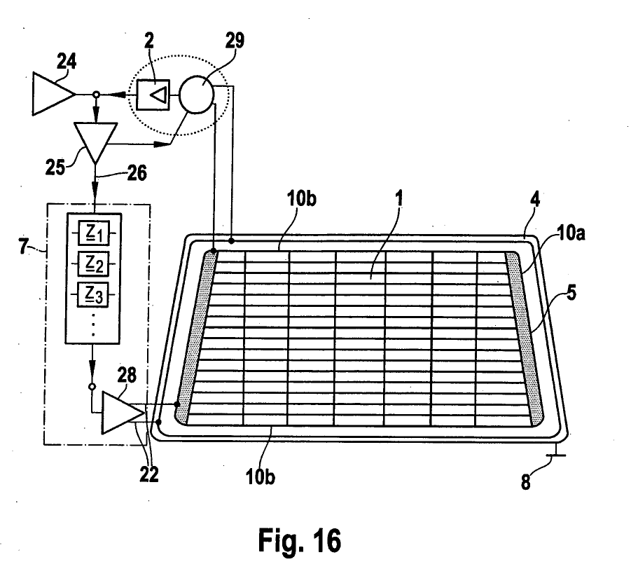

For impedance adjustment of the impedance at tap point 6b, prevailing in different switching states and therefore at different terminating impedances, to the input impedance of receiving unit 24, according to FIG. 16 an adjustment network 29 is provided upstream from antenna amplifier 2. This adjustment network 29 is advantageously controllable by diversity analyzer unit 25, so that a corresponding impedance adjustment may be made by adjustment network 29 for each selected terminating impedance 7. The control lines to terminating resistor 7 and/or terminating resistors 7 as well as to adjustment network 29 may be provided in the form of separate lines or cables or may be implemented through corresponding window coatings.

THE ANTENNA SYSTEM ACCORDING TO EXAMPLE EMBODIMENTS OF THE PRESENT INVENTION MAY BE USED FOR REAR WINDOWS AND FOR SIDE WINDOWS. IN ADDITION TO ITS USE AS A VHF ANTENNA, AS DESCRIBED ABOVE, THE ANTENNA SYSTEM ACCORDING TO EXAMPLE EMBODIMENTS OF THE PRESENT INVENTION MAY ALSO BE USED FOR VARIOUS OTHER FREQUENCY RANGES AND SERVICES, E.G., FOR AM, DAB, TV, DVB-T AND IN COMBINATION WITH OTHER DIVERSITY METHODS SUCH AS DDA (DIGITAL DIRECTIVE ANTENNA).

What is claimed is:

1. An antenna system, for diversity operation in a motor vehicle in particular, comprising the following features:
at least one cohesive high-frequency-conductive surface (1), which is insulated with respect to a surrounding grounding surface (4), e.g., the vehicle body,
at least one switchable terminating impedance (7) which is coupled to the at least one conductive surface (1) with a high resistance,
at least one tap point (6b) for antenna signals on the conductive surface (1), in particular at a high-resistance point in its outer border.

2. The antenna system as recited in claim 1, wherein the high-frequency-conductive surface (1) is implemented by a transparent conductive coating in or on a vehicle window.

3. The antenna system as recited in claim 1 or 2, wherein the high-frequency-conductive surface (1) is implemented by the conductors (1a) of the heating field in or on a vehicle window.

4. The antenna system as recited in one of claims 1 through 3, wherein the high-resistance supply lines (22) are provided between at least one tap point (6b) for the antenna signals and at least one analyzer unit (2) as well as between the high-frequency-conductive surface (1) and the at least one terminating impedance (7).

5. The antenna system as recited in claim 4, wherein the particular directional characteristic of the antenna system and thus the diversity function are adjustable through the switchable terminating impedances (7) and the high-resistance supply lines (22).

6. The antenna system as recited in one of claims 1 through 5, wherein the high-resistance coupling of the at least one terminating impedance (7) to the high-frequency-conductive surface (1) is accomplished via a conductor (1a) of the heating field or a collective conductor (5) connecting the conductors (1a) of the heating field to one another and a high-resistance supply line (22).

7. The antenna system as recited in one of claims 1 through 6, wherein the tap point (6b) for antenna signals is situated on a conductor (1a) of the heating field, in particular a high-resistance conductor located on the outer edge.

8. The antenna system as recited in one of claims 1 through 7, wherein additional antenna conductors (13a, 13b) are provided in particular perpendicular to the conductors (1a) of the heating field to influence and optionally amplify the antenna effect and/or the diversity effect and/or to adjust the terminating impedances (7) to the conductive surface (1) and/or its connection points.

9. The antenna system as recited in claim 78, wherein the additional conductors (13a, 13b) provided perpendicular to the conductors (1a) run at least partially from the upper edge to the lower edge of the heating field and are at least partially electrically connected or interrupted on the intersection points with the conductors (1a) of the heating field in such a way that a capacitive coupling comes about.

10. The antenna system as recited in one of claims 1 through 9, wherein a line structure (10c) in or on the vehicle window or a cable is provided between a switchable terminating impedance (7) and the coupling to the high-frequency-conductive surface (1).

11. The antenna system as recited in one of claims 1 through 10, wherein the at least one switchable terminating impedance (7) is implemented by electronically controllable or switchable impedance values in the form of discrete components, line segments or by voltage-controlled active components such as diodes and/or capacitance diodes.

12. The antenna system as recited in one of claims 1 through 11, wherein the high-resistance supply lines (22) and couplings are implemented through conductive coatings in or on a vehicle window of a corresponding resistance and/or conductor width.

13. The antenna system as recited in one of claims 4 through 12, wherein the conductivity of the conductive surface (1) bordered by the transparency is variable for implementation of the high-resistance supply lines (22) through appropriate structures in the conductive surface (1) and/or corresponding materials.

14. The antenna system as recited in one of claims 4 through 12, wherein the high-resistance supply lines (22) are implemented by additional conductors or conductive coatings in particular in the invisible edge area of the vehicle window.

15. The antenna system as recited in one of claims 3 through 14, wherein low-pass filters (13) are provided in the heating current circuit for decoupling the antenna structures from the heating current circuit of the heating field.

16. The antenna system as recited in one of claims 1 through 15, wherein in the case of a plurality of separate heating fields, these are combined through couplings via discrete components and/or through line couplings to form a joint high-frequency-conductive surface (1), the conductors of the heating field or additional conductors implementing this line coupling.

17. The antenna system as recited in one of claims 1 through 16, wherein in the case of at least one heating field used as an antenna structure and another antenna structure, these are combined by couplings via discrete components (19) and/or through line couplings to form a joint high-frequency-conductive surface (1), the conductors (1a) of the heating field or additional antenna structures implementing these line couplings.

18. The antenna system as recited in claim 17, wherein an analyzer unit (25) is provided which detects the antenna signal strength; the analyzer unit (25) varies the switching states of the terminating impedance(s) (7) in the sense of antenna diversity as a function of the particular antenna signal strength in such a way as to counteract a decline in antenna signal strength.

19. The antenna system as recited in claim 18, wherein the tap point (6b) for the antenna signals is connected to an adjustment network (29) for the particular impedance adjustment of the impedance prevailing at the tap point (6b) to the impedance of a receiving unit (24) in different switching states of the terminating impedance (7), the adjustment network (29) being controllable by the analyzer unit (25).
